(19) United States
(12) Patent Application Publication
(10) Pub. No.: US 2011/0133845 A1
(43) Pub. Date: Jun. 9, 2011

(54) OSCILLATOR CIRCUIT

(75) Inventor: Yuichiro INOUE, Miyazaki (JP)

(73) Assignee: OKI SEMICONDUCTOR CO., LTD., Tokyo (JP)

(21) Appl. No.: 12/958,155

(22) Filed: Dec. 1, 2010

(30) Foreign Application Priority Data
Dec. 7, 2009 (JP) 2009-277592

(51) Int. Cl. H03B 5/24; H03B 5/30

(52) U.S. Cl. 331/108 R; 331/158

(57) ABSTRACT

The present invention provides an oscillator circuit that can decrease consumed current. Namely, a second PMOS transistor is provided between a first PMOS transistor in which a constant current flows and an NMOS transistor for amplifying an oscillating signal, in order to interrupt the constant current flowing in the first PMOS transistor MP3 from flowing to a NODE4. The source of the second PMOS transistor is connected to the drain of the first PMOS transistor, the drain of the second PMOS transistor is connected to the source of the NMOS transistor and the gate of the second PMOS transistor is connected to a NODE1. The NODE1 is connected to a bias signal line via a resistance element and also connected to a signal line via a capacitor element.

### CROSS-REFERENCE TO RELATED APPLICATION

This application claims priority under 35 USC 119 from Japanese Patent Application No. 2009-277592 filed on Dec. 7, 2009, the disclosure of which is incorporated by reference herein.

### BACKGROUND OF THE INVENTION

1. Field of the Invention

The present invention relates to an oscillator circuit.

2. Description of the Related Art

Generally, an oscillator circuit that amplifies a feint oscillating signal (amplitude) generated by an oscillator element, such as a crystal oscillator element, by an amplifier circuit and outputs the signal, is known.

For example, such an oscillator circuit is described in Japanese Patent Application Laid-Open (JP-A) No. 2002-359524. The oscillator circuit includes a resonance section having an oscillator capacitor and a crystal oscillator, and an amplification section that excites the resonance section.

An example of a schematic configuration of a conventional oscillator circuit is shown in FIG. 3. A conventional oscillator circuit 100 shown in FIG. 3 includes a bias circuit section 112, an amplification section 114, an oscillator section 116, an oscillator next stage section 118, and an output terminal out (referred to below as out) 119.

The bias circuit section 112 is configured including PMOS transistors mp1, mp2, NMOS transistors mn1, mn2 and resistor r1. The bias circuit section 112 generates bias voltage signals bh, b1 whose signal levels do not depend on a power supply voltage VDD, and outputs the generated bias voltage signal bh to the amplification section 114.

The amplification section 114 is configured including a PMOS transistor mp3, NMOS transistor mn3, and a feedback resistor rf. The amplification section 114 uses a constant current generated by the PMOS transistor mp3, and amplifies an oscillating signal xt to an output signal xtb. The amplification section 114 flows a constant current, generated by the bias voltage signal bh input from the bias circuit section 112 being input to the PMOS transistor mp3, to the NMOS transistor mn3. The NMOS transistor mn3 outputs the output signal xtb, obtained by amplifying the oscillating signal xt, input to the amplification section 114 from the oscillator section 116. An output signal line of the drains of the NMOS transistor mn3 and the PMOS transistor mp3 is connected to the gate of the NMOS transistor mn3 via the feedback resistor rf.

The oscillator section 116 is configured including a crystal oscillator element x′ ta1, and capacitor elements of load capacitors cd, cg. The output signal xtb of the amplification section 114 is input to the oscillator section 116. In order to amplify the oscillating signal xt by the amplification section 114 and to output the output signal xtb, the capacitor devices cg, cd are repeatedly charged and discharged in the oscillator section 116. Accordingly, the oscillator section 116 causes the crystal oscillator element x′ tal to oscillate in oscillating operation, and outputs the oscillating signal xt to the amplification section 114. Note that, when the oscillating signal xt is Low level, the load capacitor cd is in the charging state, and the capacitor device cg is in the discharging state. When the oscillating signal xt is High level, the load capacitor cd is in the discharging state and the capacitor device cg is in the charging state.

The oscillator next stage section 118 amplifies the output signal xtb input from the amplification section 114, and outputs a square wave to the out 119.

In the oscillator circuit 100, in order to amplify the oscillating signal xt in the amplification section 114 and to the output signal xtb, as described above, charging and discharging is performed to the load capacitors cd, cg. However, when the load capacitor cd is discharging, the oscillating signal xt may be amplified to the output signal xtb by the discharge current of the load capacitor cd, even without using the constant current. In such cases, since the constant current becomes an excess current, there is a large consumed current in the oscillator circuit 100.

### SUMMARY OF THE INVENTION

The present invention provides an oscillator circuit that can reduce the consumed current.

A first aspect of the present invention is an oscillator circuit including: an amplification section that amplifies an oscillating signal input to the gate of an N-type field effect transistor and outputting from an output terminal, the amplification section including, a first P-type field effect transistor that includes, a gate applied with a bias voltage generated by a bias circuit, and a source applied with a voltage from a predetermined power supply voltage, a second P-type field effect transistor that includes, a gate connected to the gate of the first P-type field effect transistor, a source connected to the drain of the first P-type field effect transistor, and a drain connected to an output terminal for outputting an output signal, and that interrupts such that current flowing in the first P-type field effect transistor does not flow to the output terminal, due to application of the bias voltage to the gate of the first P-type field effect transistor, and the N-type field effect transistor that includes, a gate connected to the gate of the second P-type field effect transistor and also connected to the output terminal via a feedback resistor element, a source connected to ground, and a drain connected to the drain of the second P-type field effect transistor; and an oscillating section including, an oscillator element that includes, an input side connected to the output terminal, and an output side connected to the gate of the N-type field effect transistor and the oscillator element that output the oscillating signal, a first capacitor element that includes, one end connected to the input side of the oscillator element and the output terminal, and another end connected to ground, and a second capacitor element that includes, one end connected to the output side of the oscillator element and the gate of the N-type field effect transistor, and other end connected to ground.

In a second aspect of the present invention, in the above first aspect, the amplification section may further include a resistance element connected between the gate of the first P-type field effect transistor and the gate of the second P-type field effect transistor.

In a third aspect of the present invention, in the above first aspect, the amplification section may further include a third P-type field effect transistor that includes a source connected to the gate of the first P-type field effect transistor, a drain connected to the gate of the second P-type field effect transistor, and a gate connected to ground.

In a fourth aspect of the present invention, in the above first aspect, the amplification section may further include a third capacitor element connected between the gate of the second P-type field effect transistor and the gate of the N-type field effect transistor.

In a fifth aspect of the present invention, in the above first aspect, the oscillator element of the oscillating section may be a crystal oscillator element.

According to the above aspects, the present invention can reduce consumed current by an oscillator circuit.

### BRIEF DESCRIPTION OF THE DRAWINGS

Exemplary embodiments of the present invention will be described in detail based on the following figures, wherein:

FIG. 1 is a diagram showing an example of a schematic configuration of an oscillator circuit according to a first exemplary embodiment;

FIG. 2 is a diagram showing an example of a schematic configuration of an oscillator circuit according to a second exemplary embodiment; and

FIG. 3 is a diagram showing an example of a schematic configuration of a conventional oscillator circuit.

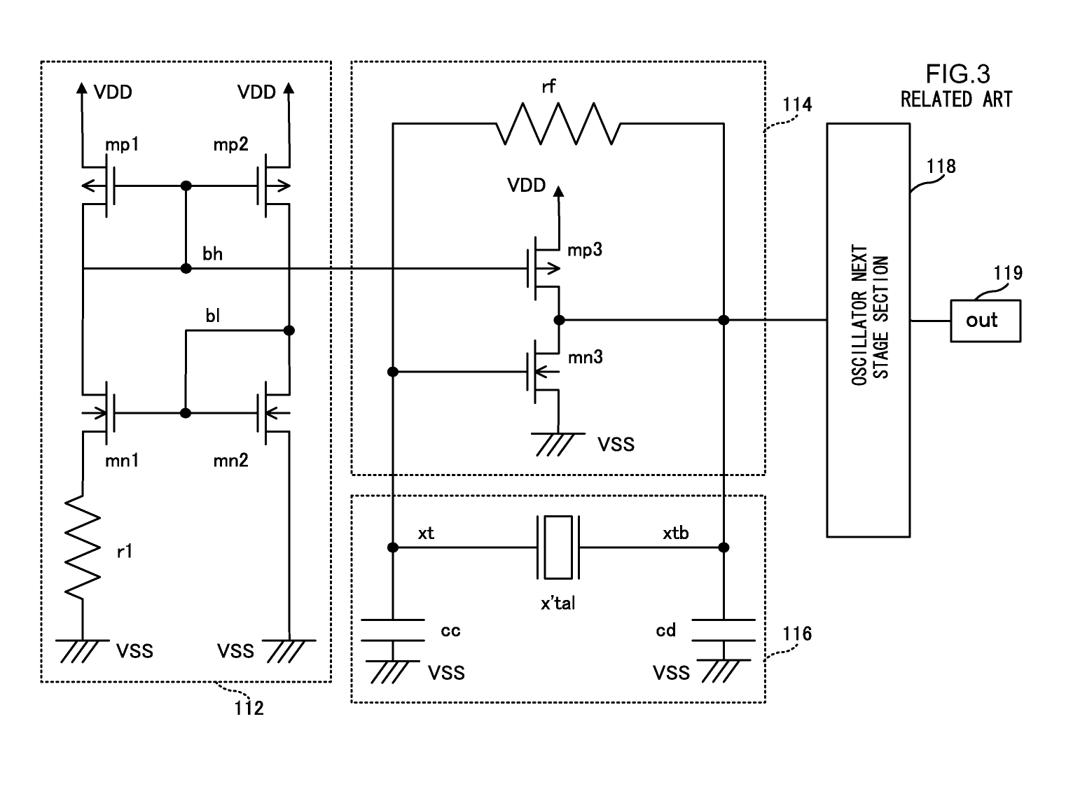

### DETAILED DESCRIPTION OF THE INVENTION

### First Exemplary Embodiment

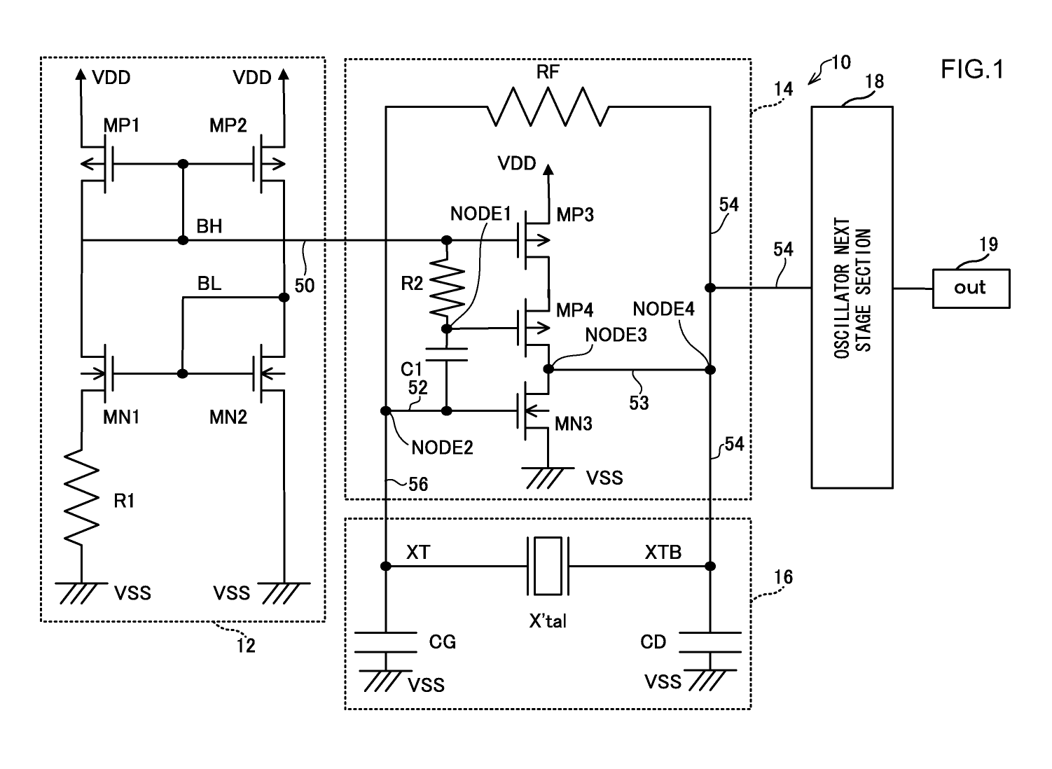

Detailed explanation regarding an oscillator circuit of a first exemplary embodiment of the present invention, will be described with reference to the drawings. FIG. 1 shows an example of a schematic configuration of an oscillator circuit 10 of the present exemplary embodiment. Note that, in the explanation below, a P-type field effect transistor is referred to as a PMOS transistor, and an N-type field effect transistor is referred to as an NMOS transistor.

First, detailed explanation follows regarding a schematic configuration of the oscillator circuit 10 of the present exemplary embodiment. The oscillator circuit 10 of the present exemplary embodiment is configured including a bias circuit section 12, an amplification section 14, an oscillator section 16, an oscillator next stage section 18, and an output terminal out (referred to below as out) 19.

The bias circuit section 12 generates and outputs to the amplification section 14 a bias voltage signal BH of signal level that does not depend on a predetermined power supply voltage VDD (referred to below as VDD). The bias circuit section 12 is connected to the amplification section 14 through a bias signal line 50. Generation of a constant current by a PMOS transistor MP3 of the amplification section 14 is controlled by the bias voltage signal BH. The bias circuit section 12 is configured including PMOS transistors MP1, MP2, NMOS transistors MN1, MN2 and a resistor element R1.

As long as the bias circuit section 12 is one that can generate and output to the amplification section 14 the bias voltage signal BH of voltage value desired by the amplification section 14, there is no limitation to the bias circuit section 12 schematic configured as shown in FIG. 1, and another circuit configuration may be employed.

The amplification section 14 is an amplifier (amplification circuit) that amplifies an oscillating signal XT input from the oscillator section 16 as an output signal XTB. The degree of amplification of the amplification section 14 is proportional to the capacities of the capacity elements CD, CG of the oscillator section 16. The amplification section 14 is configured including the PMOS transistors MP3, MP4, an NMOS transistor MN3, a resistor element R2 and a capacitor element C1.

The bias signal line 50 is connected to the gate of the PMOS transistor MP3, the predetermined power supply voltage VDD is connected to the source of the PMOS transistor MP3, and the source of the PMOS transistor MP4 is connected to the drain of the PMOS transistor MP3. The PMOS transistor MP3 adopts the ON state when input with the bias voltage signal BH via the bias signal line 50, and generates and outputs a constant current.

The gate of the PMOS transistor MP4 is connected to a NODE1, and the source of the PMOS transistor MP4 is connected to the drain of the PMOS transistor MP3. The gate of the NMOS transistor MN3 is connected to a NODE2 via a signal line 52, and the source of the NMOS transistor MN3 is connected to a predetermined ground voltage VSS (referred to below as VSS). The drain of the PMOS transistor MP4 and the drain of the NMOS transistor MN3 are connected to a NODE3. The NODE3 is connected to an output signal line 54 via a signal line 53 and a NODE4, and the output signal XTB is output via the output signal line 54. The output signal line 54 is connected to the NODE2 via a feedback resistor RE. The oscillating signal line 56 is connected to the NODE2.

The resistor element R2 and the capacitor element C1 are connected between the bias signal line 50 and the signal line 52. One end of the resistor element R2 is connected to the bias signal line 50, and the other end is connected to the NODE1. The resistor element R2 is a filter resistor that avoids an influence of the oscillating signal XT propagating through the signal line 52 to the bias signal line 50. One end of the capacitor element C1 is connected to the signal line 52, and the other end of the capacitor element C1 is connected to the NODE1. The capacitor element C1 stabilizes the oscillating signal XT input to the PMOS transistor MP4 via the NODE1.

The oscillator section 16 is configured including capacitor elements CD, CG and a crystal oscillator element X′ ta1. The capacitor elements CD, CG charge and discharge charge for generating electrodes of the crystal oscillator element X′ tal, and stabilize and determine the oscillating frequency of oscillation of the crystal oscillator element X′ tal. The capacities of the capacitor elements CD, CG are configured to have appropriate capacities to obtain the desired oscillating frequency and amplitude. The capacitor elements CD, CG are preferably disposed in the vicinity of the terminals of the crystal oscillator element X′ tal, are particularly preferably disposed adjacent thereto. One end of the capacitor element CD is connected to the crystal oscillator element X′ ta1 and the NODE4 of the amplification section 14. The other end of the capacitor element CD is connected to VSS. Similarly, one end of the capacitor element CG is connected to the crystal oscillator element X′ tal and to the NODE2 of the amplification section 14, while the other is connected to VSS.

The output signal line 54 and an oscillating signal line 56 are connected to the crystal oscillator element X′ tal. The crystal oscillator element X′ tal oscillates when applied with the output signal XTB from the amplification section 14 via the output signal line 54. The oscillated oscillating signal XT is output to the NODE2 of the amplification section 14 via the oscillating signal line 56.

In the present exemplary embodiment, the oscillator section 16 is an oscillator circuit that employs the crystal oscillator element X′ ta1 to derive the oscillating signal XT. However, the present invention is not limited thereto. Configuration may be made with the oscillator section 16 configured as an oscillator circuit that employs, for example, another element or the like to derive the oscillating signal, as long configuration is made such that the desired oscillating frequency and amplitude can be obtained. For example, an oscillator circuit employing a ceramic oscillator element, a CR oscillator circuit, an LC tunable oscillator circuit or the like, may be employed in the oscillator section 16. The oscillator section 16 preferably employs a crystal oscillator element X′ tal as the oscillator circuit, in order to oscillate stably with high frequency precision, such that oscillation can be tuned to the desired voltage level and amplitude.

The oscillator next stage section 18 has functionality to amplify the output signal XTB that has been input from the amplification section 14 by the output signal line 54, and output as a square wave to the out 19. A known output circuit or the like having the above function may be employed in the oscillator next stage section 18.

In the present exemplary embodiment, the bias circuit section 12, the amplification section 14, the oscillator next stage section 18, and the out 19 are consolidated onto a LSI (device) of a single chip. Further, in the present exemplary embodiment, the oscillator section 16 is set externally (attached externally) to the single chip LSI. However, there is no limitation thereto, and in another exemplary embodiment, all of these sections may be consolidated onto a single chip LSI, or mounted independently on an LSI of plural chips.

Detailed explanation regarding the operation of the oscillator circuit 10 of the present exemplary embodiment is described.

The bias voltage signal BH of voltage value the same as, or lower than, a threshold value is applied from the bias circuit section 12 to the gate of the PMOS transistor MP3 via the bias signal line 50. When the bias voltage signal BH is applied to the gate of the PMOS transistor MP3, the PMOS transistor MP3 terns to an ON state, the voltage from the VDD acts, and a constant current flows in the PMOS transistor MP3. Voltage is thereby applied to the gate of the NMOS transistor MN3, and the NMOS transistor MN3 terns to an ON state. The voltage (or current) applied thereby to the two ends of the crystal oscillator element X′ ta1 of the oscillator section 16 acts as a trigger, and the crystal oscillator element X′ tal starts oscillation. As a result, the oscillating signal XT is output from the oscillator section 16 to the amplification section 14. In the amplification section 14, the oscillating signal XT is amplified by the NMOS transistor MN3 and is output as the output signal XTB.

When the voltage level of the oscillating signal XT is Low level, the PMOS transistor MP4 terns to an ON state due to the voltage level applied to the gate of the PMOS transistor MP4 via the capacitor element C1 and the NODE1 being the oscillating signal XT at Low level, and due to the bias voltage signal BH being applied to the gate of the PMOS transistor MP4 via the resistor element R2 and the NODE1. Due to the PMOS transistor MP3 also being in the ON state, a constant current flows in the PMOS transistor MP3 and the PMOS transistor MP4. The NMOS transistor MN3 terns to the OFF state due to the oscillating signal XT of Low level voltage being applied to the gate of the NMOS transistor MN3. Accordingly, the constant current flows into the capacitor element CD via the signal line 53 and the output signal line 54. The capacitor element CD is charged by the inflowing constant current.

When the voltage level of the oscillating signal XT is High level, the PMOS transistor MP4 terns to an OFF state due to the oscillating signal XT of High level voltage being applied to the gate of the PMOS transistor MP4 via the capacitor element C1 and the NODE1, and due to the bias voltage signal BH being applied to the gate of the PMOS transistor MP4 via the resistor element R2 and the NODE1. Constant current does not flow due to the PMOS transistor MP3 being in the ON state and the PMOS transistor MP4 being in the OFF state. The NMOS transistor MN3 terns to an ON state due to the oscillating signal XT of High level voltage being applied to the gate. Accordingly, discharge current from the capacitor element CD flows in the amplification section 14 in place of constant current. Therefore, the NMOS transistor MN3 can amplify the oscillating signal XT using this discharge current. Consequently, the amplification section 14 can output the output signal XTB.

In the present exemplary embodiment, the voltage level of the Low level oscillating signal XT is a voltage less than the threshold value of the NMOS transistor MN3. In the present exemplary embodiment, the voltage level of High level is a voltage that is the threshold value of the NMOS transistor MN3 or greater.

The gate of the PMOS transistor MP4 of the amplification section 14 in the present exemplary embodiment is applied with the bias voltage signal BH via the resistor element R2. Accordingly, the PMOS transistor MP4 is controlled ON or OFF by the oscillating signal XT centered around the bias voltage signal BH. Consequently, the amplification section 14 can perform stable operation according to the voltage level of the oscillating signal XT.

As explained above, in the oscillator circuit 10 according to the present exemplary embodiment, the PMOS transistor MP4 is provided between the PMOS transistor MP3 in which constant current flows, and the NMOS transistor MN3 for amplifying the oscillating signal XT. The PMOS transistor MP4 interrupts flow to the NODE4 (NODE3) of the constant current flowing in the PMOS transistor MP3. The source of the PMOS transistor MP4 is connected to the drain of the PMOS transistor MP3, the drain of the PMOS transistor MP4 is connected to the source of the NMOS transistor MN3, and the gate of the PMOS transistor MP4 is connected to the NODE1. The NODE 1 is connected to the bias signal line 50 via the resistor element R2, and also is connected to the signal line 52 via the capacitor element C1.

Accordingly, when the oscillating signal XT is High level, constant current stops flowing due to the PMOS transistor MP4 being in the ON state. Charge is also discharged from the capacitor element CD due to the NMOS transistor MN3 being in the ON state. As a result, the NMOS transistor MN3 amplifies the oscillating signal XT using the discharge current due to discharge of the capacitor element CD, in place of the constant current.

In the amplification section 14 of the oscillator circuit 10 of the present exemplary embodiment, constant current does not flow when the oscillating signal XT is High level. Consequently, the oscillator circuit 10 of the present exemplary embodiment can decrease the consumed current.

### Second Exemplary Embodiment

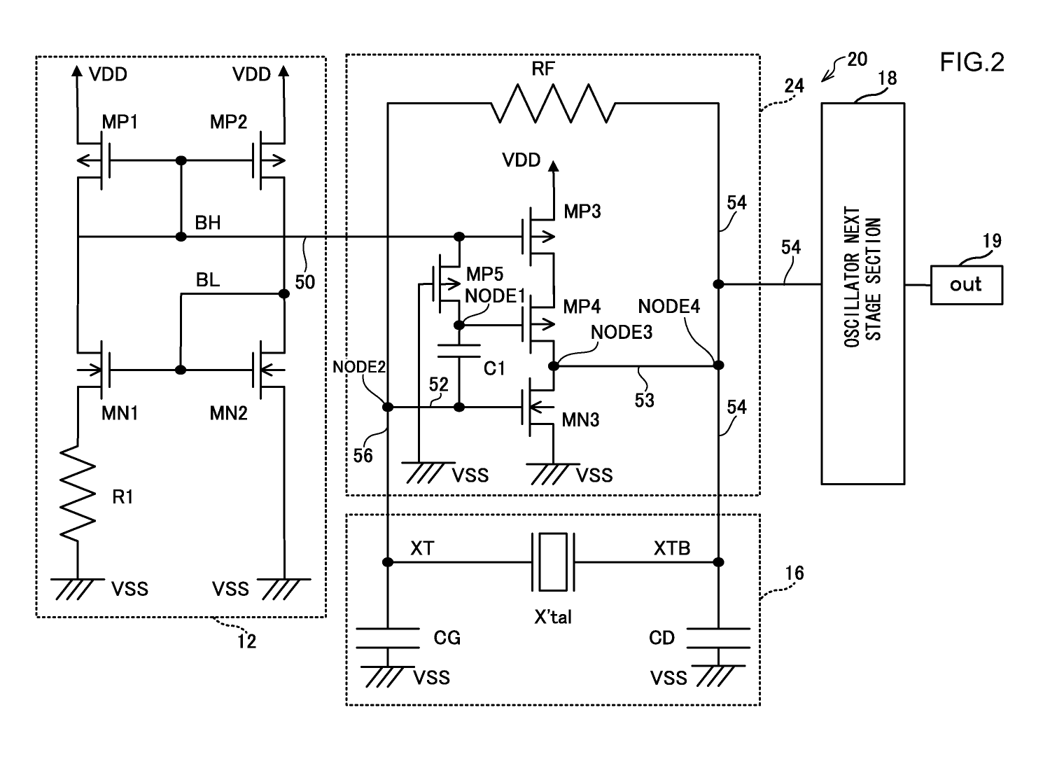

Detailed explanation regarding an oscillator circuit of a second exemplary embodiment of the present invention, with reference to the drawings is described. FIG. 2 shows an example of a schematic configuration of an oscillator circuit 20 of the present exemplary embodiment. A portion of the configuration of an amplification section 24 in the oscillator circuit 20 of the present exemplary embodiment, differs from a portion of the configuration of the amplification section 14 of the oscillator circuit 10 of the first exemplary embodiment. However, since other sections thereof are of substantially the same configuration, the same reference numerals are applied and detailed explanation thereof is omitted. Furthermore, since the operation of the present exemplary embodiment is similar to the operation of the first exemplary embodiment, except for the operation of the PMOS transistor MP5, detailed explanation is also omitted.

The amplification section 24 of the present exemplary embodiment is configured with the PMOS transistor MP5 in place of the resistor element R2 of the amplification section 14 of the first exemplary embodiment. The source of the PMOS transistor MP5 is connected to the bias signal line 50, and the drain of the PMOS transistor MP5 is connected to the NODE1. The gate of the PMOS transistor MP5 is connected to a predetermined ground voltage VSS. The PMOS transistor MP5 is accordingly always in the OFF state. Accordingly, the bias voltage signal BH is applied to the gate of the PMOS transistor MP4 via the NODE1. Consequently, the PMOS transistor MP4 is controlled ON or OFF by the oscillating signal XT, centered around the bias voltage signal BH.

Generally, the resistance value of the resistance (the resistor element R2 of the first exemplary embodiment) that functions as a filter to suppress influence of the oscillating signal XT on the PMOS transistor MP3 becomes greater, when the frequency at which the crystal oscillator element X′ ta1 is placed in oscillating operation the low. When there is no large resistance material for a sheet resistor, this leads to an increase of a surface area in the resistance element, in order to achieve a large resistance value.

However, in the present exemplary embodiment, due to the PMOS transistor MP5 always being in the OFF state, influence of the oscillating signal XT to the PMOS transistor MP3 can be suppressed with greater certainty. Furthermore, a surface area increase of the oscillator circuit 20 can be suppressed.

What is claimed is:

1. An oscillator circuit comprising:
an amplification section that amplifies an oscillating signal input to the gate of an N-type field effect transistor and outputting from an output terminal, the amplification section comprising,
a first P-type field effect transistor that includes, a gate applied with a bias voltage generated by a bias circuit, and a source applied with a voltage from a predetermined power supply voltage,
a second P-type field effect transistor that includes, a gate connected to the gate of the first P-type field effect transistor, a source connected to the drain of the first P-type field effect transistor, and a drain connected to an output terminal for outputting an output signal, and that interrupts such that current flowing in the first P-type field effect transistor does not flow to the output terminal, due to application of the bias voltage to the gate of the first P-type field effect transistor, and
the N-type field effect transistor that includes, a gate connected to the gate of the second P-type field effect transistor and also connected to the output terminal via a feedback resistor element, a source connected to ground, and a drain connected to the drain of the second P-type field effect transistor; and an oscillating section comprising,
an oscillator element that includes, an input side connected to the output terminal, and an output side connected to the gate of the N-type field effect transistor and the oscillator element that output the oscillating signal,
a first capacitor element that includes, one end connected to the input side of the oscillator element and the output terminal, and another end connected to ground, and
a second capacitor element that includes, one end connected to the output side of the oscillator element and the gate of the N-type field effect transistor, and other end connected to ground.

2. The oscillator circuit of claim 1, wherein the amplification section further comprises a resistance element connected between the gate of the first P-type field effect transistor and the gate of the second P-type field effect transistor.

3. The oscillator circuit of claim 1, wherein the amplification section further comprises a third P-type field effect transistor that includes a source connected to the gate of the first P-type field effect transistor, a drain connected to the gate of the second P-type field effect transistor, and a gate connected to ground.

4. The oscillator circuit of claim 1, wherein the amplification section further comprises a third capacitor element connected between the gate of the second P-type field effect transistor and the gate of the N-type field effect transistor.

5. The oscillator circuit of claim 1, wherein the oscillator element of the oscillating section is a crystal oscillator element.
